(19) United States
(12) Patent Application Publication
(10) Pub. No.: US 2025/0133863 A1
(43) Pub. Date: Apr. 24, 2025

(54) MICROSTRUCTURED LIGHT-COLLECTION FILM STRUCTURE

(71) Applicant: Hui-Hsiung LIN, Zhunan Township (TW)

(72) Inventor: Hui-Hsiung LIN, Zhunan Township (TW)

(21) Appl. No.: 18/924,071

(22) Filed: Oct. 23, 2024

Related U.S. Application Data
(60) Provisional application No. 63/545,483, filed on Oct. 24, 2023.

(51) Int. Cl. H01L 31/054; H01L 31/0216; H01L 31/0445; H01L 31/048

(52) U.S. Cl. CPC H10F 77/484; H10F 19/30; H10F 19/804; H10F 77/315

(57) ABSTRACT

Provided are a microstructured optical film structure with a latitude position optimization function applicable to a solar light-collection module installed (operated) in a direction perpendicular (orthogonal) to sunlight or a direction perpendicular (orthogonal) to the ground and a method of using the light-collection film to collect sunlight or ambient light. The microstructured optical film structure includes a solar (PV) module. The module is applicable to various inorganic/organic photovoltaic chips/photoelectric sensors/modules thereof and includes optimized microstructured optical film layers capable of receiving different light rays incident at various angles from different latitude spaces.

### BACKGROUND

### Technical Field

The present invention relates to an optical film, and in particular, to a microstructured light-collection film structure with a latitude position optimization function and applicable to installation/operation in a direction perpendicular to sunlight or a direction perpendicular to the ground.

### Related Art

In California, USA, all new residential buildings are required to achieve net zero emission by 2020, and the same requirements are put forward for commercial buildings by 2030 (CA Energy Efficiency Strategic Plan, California Public Utilities Commission, 2018. http://www.cpuc.ca.gov/General.aspx?id=4125). Therefore, due to these strict energy policies and abundant available surface area in the building environment, building-integrated solar modules (Building-integrated photovoltaics, BIPV) have attracted people's interest. A recent study confirmed this idea and found that only BIPV can meet 32% of electricity demands of EU (D. Mueller, Merck, H. Buerkstuemmer, R. Vignal, P. Mace, Technical Evaluation of BIPV power generation potential in EU-28. http://becquerelinstitute.org/wp-content/uploads/2014/08/6DO-8-final-BIPV-Technical-Potential.pdf, 2016, 2518-2522). Therefore, the research in this field is growing.

Correct installation and specific orientation of solar cells are the basic criteria to improve efficiency. Traditionally, installation and selection of a specific direction of a solar panel cause a surface of the solar panel to be perpendicular (orthogonal) to the direction of incident light from the sun most of the time. Basically, the best direction of traditional solar panels is that surface normals thereof face the sun. This direction can achieve maximum power generation efficiency, because it can maximize a projected area of solar panels when viewed from the direction of the sun. However, the sun crosses the sky in one day and reaches different zeniths (that is, the maximum height at noon above the horizon) every day based on sunshine durations of the year. In ideal conditions, there are two types of installation manners for a traditional solar panel. One is a sun tracking type installation, that is, in order to maximize transmission efficiency of solar energy, a traditional solar panel is to be installed on a system of a precision sun tracking module. The system may dynamically rotate the panel (tracking an azimuth angle and an altitude angle of the sun) in two axes in a day, so that the panel can track the sun, and adjust an inclination angle (an angle formed between a panel plane and an approximate plane of a surface of the earth where the panel is located) to compensate for a height of the sun above the horizon with sunrise, sunset, and seasonal changes. However, the sun tracking system needs to rely on installation of bulky bases and expensive and confidential trackers, is prone to failures and errors (a deviation is required to be less than ±0.1°), and is impractical for many system installations in urban commercial areas. The other type is a common fixed installation, in which the traditional panel is installed facing south (that is, a ground projection of a surface perpendicular to an active surface of the panel points to the south), and the inclination angle is equal to a position where the panel is installed at latitude. The details mentioned above are based on the Northern Hemisphere as an example. For the Southern Hemisphere, they should be adjusted to face north.

Using the conventional technology suitable for radiating solar energy or transferring the solar energy to solar cell chips/elements for concentration through media, a plurality of concentrators, such as a compound parabolic concentrator (CPC) has been disclosed below. A planar concentrator, such as a holographic planar concentrator (HPC), includes a planar high transparent plate and a holographic recording optical element installed on a surface thereof or a method for concentrating solar energy on a hologram on an adjacent photovoltaic chip. A spectrum-splitting concentrator (SSC) includes a plurality of single-junction solar cells, where these cell chips may operate efficiently in different corresponding spectral bands after being individually optimized, and luminous solar concentrators (LSCs) composed of transparent plastic sheets containing absorption and emission materials with solar cells attached to their edges.

According to the literature, one of the technologies considered by BIPV is to incorporate the luminous solar concentrator (LSC) into the building envelope. The LSC is composed of a transparent plastic sheet containing absorption and emission (fluorescent) materials, with a solar cell chip attached to the edge. The LSC has been shown to be able to efficiently receive light at a wide range of incident angles without the need for a tracking system. This is an advantage often mentioned in the literature but not widely discussed in industrial applications. A wedge-shaped (Performance of wedge-shaped luminescent solar concentrators employing phosphor films and annual energy estimation case studies, Renewable Energy 160 (2020) 513-525.) LSC exhibits an enhanced ability to capture sunlight at an incident angle in a range of 20-40°. (M. D. Hughes, C. Maher, D.-A. Borca-Tasciuc, D. Polanco, D. Kaminski, Performance comparison of wedge-shaped and planar luminescent solar concentrators, Renew. Energy 52 (2013) 266e272, https://doi.org/10.1016/j.renene.2012.10.034.) Most LSC products also use organic dyes, inorganic phosphors, or quantum dots as luminescent materials. These quantum dots and organic dyes may be degraded by ultraviolet radiation, while inorganic phosphors may lead to significant scattering losses. (D. K. G. de Boer, D. J. Broer, M. G. Debije, W. Keur, A. Meijerink, C. R. Ronda, P. P. C. Verbunt, Progress in phosphors and filters for luminescent solar concentrators, Optic Express 20 (2012) A395, https://doi.org/10.1364/oe.20.00a395.) For the above existing technologies, refer to US patents US20130312811A1, US20150194555A1, and US20150107665A1.

At present, a key issue faced by the traditional solar energy industry is how to reduce system costs of conversion efficiency per energy unit (per kilowatt-hour: KWh). The mainstream technologies being explored to decrease the cost per kilowatt of solar energy have two major goals: one is to improve efficiency of a solar cells including a solar module, and the other is to radiate more solar energy or transfer the solar energy to a solar cell chip/element through a medium. In particular, this kind of technology includes development of diffractive (grating/holographic) films, fluorescent polymers, organic materials/dye-sensitized solar cells, and the like, to replace solar cell chips based on expensive semiconductor materials, or sun tracking concentrating systems, use of high-efficiency small-area photovoltaic crystal devices (such as III-V compound semiconductors), and implementation of low-cost heat collectors and solar cell concentrators. Although the use of semiconductor-based solar cell chips may be apparently reduced, and a potentially huge vision is revealed, this type of traditional solar system has always relied on a large amount of land area, even extending to reservoirs and ecological ponds, and fertile farmlands/pastures/forests are to be eventually irrationally destroyed successively and cannot be restored. What is more obvious is that the application of traditional solar modules or systems to urban residential areas is still extremely poor or even helpless. Looking around the world, solar cell modules/systems in residential buildings (the modules/systems can only be applied to confined small roof spaces) around the world are usually produced by using glass plates and aluminum frame-type traditional silicon solar cell chips, and glass and silicon crystal materials constitute the main cost of the modules. Therefore, if a layer of microstructured optical film with a latitude position optimization function can be introduced under the premise of standard product modules, the microstructured optical film is applicable to a real building integrated solar module/system (BIPV/BIPVs) installed/operated in a direction perpendicular to sunlight or a direction perpendicular to the ground and capable of collecting sunlight or ambient light with high efficiency and gain, thereby greatly improving power generation efficiency of the system and reducing the levelized cost of electricity (LCOE) per kilowatt-hour.

### SUMMARY

Based on the above reasons, an object of the present invention to provide a microstructured light-collection film structure, in which a microstructured profile defined in a specific latitude range is optimized based on facing directions of different light-facing faces of microstructures on an optical film, to collect solar energy/ambient light in a direction perpendicular to sunlight or a direction perpendicular to the ground, so as to achieve a real building integrated solar module/system (BIPV/BIPVs) capable of collecting sunlight or ambient light with high efficiency and gain, thereby greatly improving power generation efficiency of the system and reducing the levelized cost of electricity (LCOE) per kilowatt-hour.

In order to achieve the above object, the present invention provides a microstructured light-collection film structure, comprising: a normal light-receiving optical film, having a light-receiving face; and a plurality of microstructures, arranged in an array and arranged on the light-receiving face of the normal light-receiving optical film, wherein each of the microstructures comprises a bottom face, a first light-facing face, a second light-facing face, and a third light-facing face, the first light-facing face extends upward from an end of the bottom face, a first interior angle is formed between the first light-facing face and the bottom face, the second light-facing face is connected to an end of the first light-facing face away from the bottom face and extends upward, a second interior angle is formed between the second light-facing face and the first light-facing face, one end of the third light-facing face is connected to the end of the second light-facing face away from the end thereof connected to the first light-facing face and extends downward, and an other end of the third light-facing face is connected to an end of the bottom face away from the end thereof connected to the first light-facing face and is connected to various inorganic/organic photovoltaic chips/photoelectric sensors/and modules thereof.

In some embodiments, the third light-facing face has a convex arc in the form of a free-form surface.

In some embodiments, the microstructured light-collection film structure further comprises an anti-reflective film covering the microstructures, wherein the anti-reflective film has a first refractive index n₁.

In some embodiments, each of the microstructures has a second refractive index n₂, and the first refractive index n₁ is less than the second refractive index n₂.

In some embodiments, the normal light-receiving optical film has a third refractive index n₃, and the second refractive index n₂ is less than the third refractive index n₃.

In some embodiments, the microstructured light-collection film structure further comprises an optical adhesive arranged below the normal light-receiving optical film, wherein the optical adhesive has a fourth refractive index n₄, and the third refractive index n₃ is less than the fourth refractive index n₄.

In some embodiments, the first interior angle is greater than or equal to 50° and less than or equal to 80°.

In some embodiments, the second interior angle is greater than or equal to 120° and less than or equal to 175°.

In some embodiments, the array arrangement is a symmetrical array arrangement, comprising at least a symmetrical circular array arrangement, a symmetrical polygonal array arrangement, and a symmetrical single-axis array arrangement.

In some embodiments, the array arrangement is a linear array arrangement, comprising at least a circular linear array arrangement, a polygonal linear array arrangement, and a single-axis linear array arrangement.

The technical features and advantages of the present disclosure have been broadly summarized above, so that the detailed description of the present disclosure below can be better understood. Other technical features and advantages forming the subject matter of the patent application of the present disclosure are to be described below. A person with ordinary knowledge in the technical field of the present disclosure should understand that the concepts and specific embodiments disclosed below may be used quite easily to modify or design other structures or processes to achieve the same object as the present disclosure. A person with ordinary knowledge in the technical field of the present disclosure should also understand that such equivalent constructions cannot depart from the spirit and scope of the present disclosure as defined by the appended patent application scope.

### BRIEF DESCRIPTION OF THE DRAWINGS

FIG. 1 is a schematic top view showing a first embodiment of a microstructured light-collection film structure of the present invention in a symmetrical two-dimensional array arrangement and receiving light multi-dimensionally.

FIG. 2a is a schematic cross-sectional view taken along a section line A-A of FIG. 1.

FIG. 2b is schematic cross-sectional view taken along the section line A-A of FIG. 1.

FIG. 3 is a schematic top view showing a first embodiment of a microstructured light-collection film structure of the present invention in another symmetrical array arrangement and receiving light multi-dimensionally.

FIG. 4a is a schematic cross-sectional view of a microstructured light-collection film structure according to the present invention applied to a solar module and taken along a section line B-B of FIG. 3.

FIG. 4b is a schematic cross-sectional view of a microstructured light-collection film structure according to the present invention applied to a solar module and taken along the section line B-B of FIG. 3.

FIG. 5 is a 3D top view of a microstructured light-collection film structure according to the present invention.

FIG. 6a is a schematic cross-sectional view of a microstructured light-collection film structure according to the present invention installed in a direction perpendicular (orthogonal) to the ground and taken along a section line C-C of FIG. 5.

FIG. 6b is a schematic cross-sectional view of a microstructured light-collection film structure according to the present invention installed in a direction perpendicular (orthogonal) to the ground and taken along a section line C-C of FIG. 5.

FIG. 7a is a schematic top view showing a microstructured light-collection film structure according to a second embodiment of the present invention in a linear array arrangement and receiving light multi-dimensionally.

FIG. 7b is a schematic top view showing a microstructured light-collection film structure according to a second embodiment of the present invention in another linear array arrangement and receiving light multi-dimensionally.

FIG. 8a is a schematic cross-sectional view of a microstructured light-collection film structure according to the present invention applied to a solar module and taken along a section line C-C of FIG. 7a.

FIG. 8b is a schematic cross-sectional view of a microstructured light-collection film structure according to the present invention applied to a solar module and taken along the section line C-C of FIG. 7a.

FIG. 9a is an embodiment in which a microstructured light-collection film structure according to the present invention is installed (operated) in a direction perpendicular (orthogonal) to the ground.

FIG. 9b is an embodiment in which a microstructured light-collection film structure according to the present invention is installed (operated) in a direction perpendicular (orthogonal) to the ground.

FIG. 10a is an embodiment in which a microstructured light-collection film structure according to the present invention is applied to a solar module and installed (operated) in a direction perpendicular (orthogonal) to the ground.

FIG. 10b is an embodiment in which a microstructured light-collection film structure according to the present invention is applied to a solar module and installed (operated) in a direction perpendicular (orthogonal) to the ground.

FIG. 11 is a schematic diagram of a curve showing a functional relationship between photoelectric conversion efficiency and a solar flux concentration of a microstructured light-collection film structure according to the present invention.

### DETAILED DESCRIPTION

Specific implementations of the present invention are described in detail below in combination with specific situations.

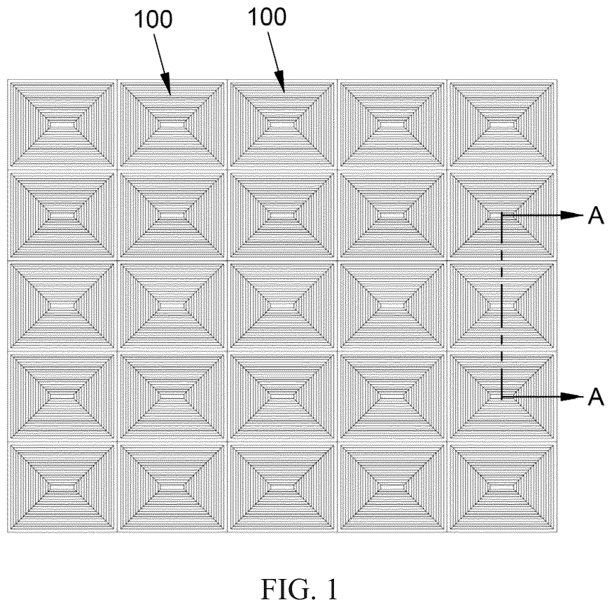

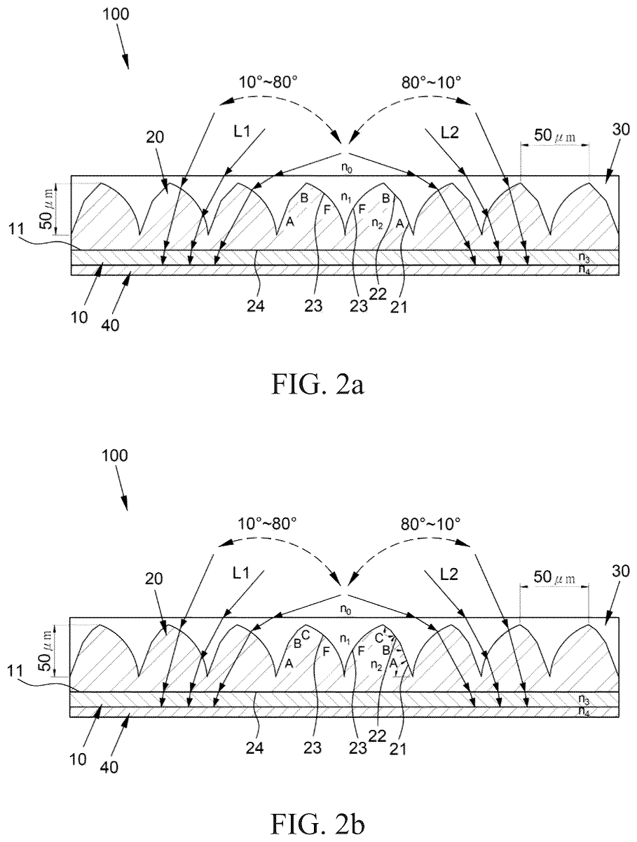

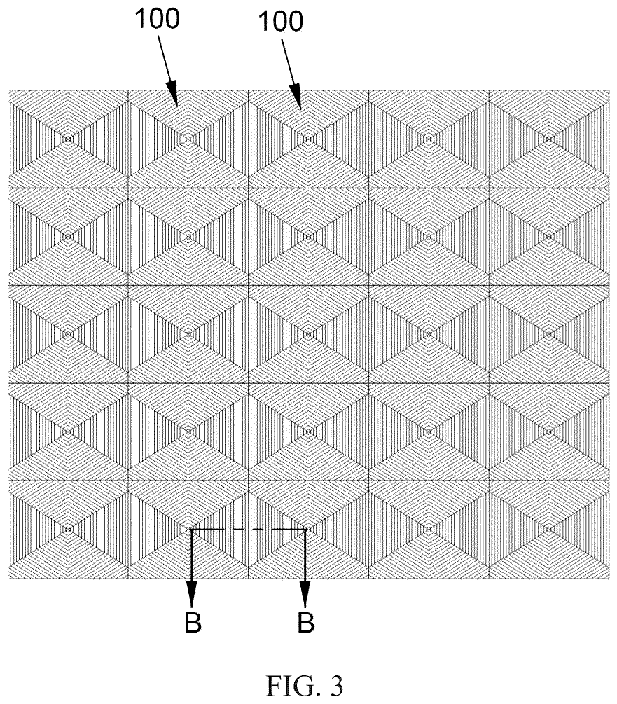

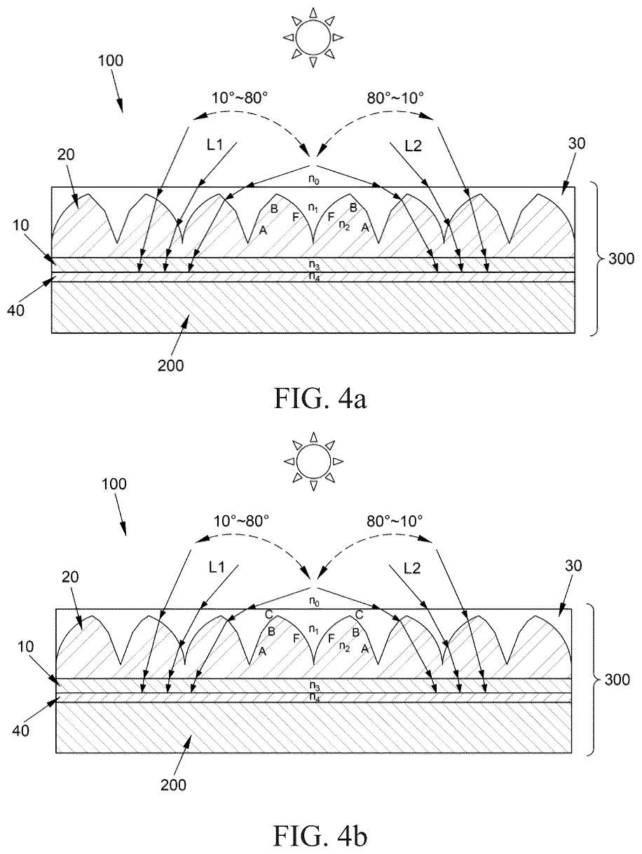

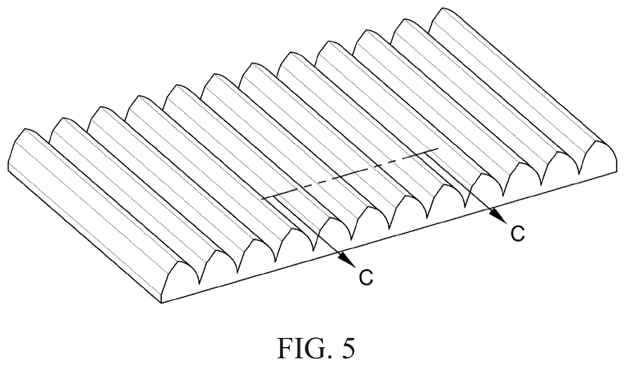

FIG. 1 is a schematic top view showing a first embodiment of a microstructured light-collection film structure of the present invention in a symmetrical two-dimensional array arrangement and receiving light multi-dimensionally. FIG. 2a to FIG. 2b are schematic cross-sectional views taken along the section line A-A of FIG. 1. FIG. 3 is a schematic top view showing a first embodiment of a microstructured light-collection film structure of the present invention in another symmetrical array arrangement and receiving light multi-dimensionally. FIG. 4a to FIG. 4b are schematic cross-sectional views of a microstructured light-collection film structure according to the present invention applied to a solar module and taken along a section line B-B of FIG. 3.

Referring to FIG. 1 and FIG. 2a to FIG. 2b, a microstructured light-collection film structure 100 according to the first embodiment of the present invention includes a normal light-receiving optical film 10 and a plurality of microstructures 20.

The normal light-receiving optical film 10 may have a light-receiving face 11. In some embodiments, the normal light-receiving optical film has a third refractive index n₃.

Referring to FIG. 1 and FIG. 3, the plurality of microstructures 20 may be in an array arrangement and arranged on the light-receiving face 11 of the normal light-receiving optical film 10. The array arrangement may be a symmetrical array arrangement, including at least a symmetrical circular array arrangement, a symmetrical polygonal array arrangement, and a symmetrical single-axis array arrangement. In FIG. 1, the array arrangement is a symmetrical quadrilateral (offset) array arrangement, and in FIG. 3, the array arrangement is a symmetrical quadrilateral (centered) array arrangement.

Referring to FIG. 2a to FIG. 2b again, each microstructure 20 may have a second refractive index n₂, and may include a bottom face 24, a first light-facing face 21, a second light-facing face 22, and a third light-facing face 23. The first light-facing face 21 may extend upward from an end of the bottom face 24, and a first interior angle A is formed between the first light-facing face 21 and the bottom face 24. In some embodiments, the first interior angle A may be greater than or equal to 50° and less than or equal to 80°. In FIG. 2a, the first interior angle A is illustrated as 70°. The second light-facing face 22 may be connected to an end of the first light-facing face 21 away from an end thereof connected to the bottom face 24 and extend upward, and a second interior angle B is formed between the second light-facing face 22 and the first light-facing face 21. In some embodiments, the second interior angle B may be greater than or equal to 120° and less than or equal to 175°. In FIG. 2a, the second interior angle B is illustrated as 150°. One end of the third light-facing face 23 may be connected to an end of the second light-facing face 22 away from an end thereof connected to the first light-facing face 21 and extend downward, and an other end of the third light-facing face 23 is connected to an end of the bottom face 24 away from the end thereof connected to the first light-facing face 21. In some embodiments, the third light-facing face 23 has a convex arc F in the form of a free-form surface. In some embodiments, a height of each microstructure 20 may be 50 μm, and a distance between two adjacent microstructures 20 may be 50 μm, but the present invention is not limited thereto.

As shown in FIG. 2a, the convex arcs F are periodically and two-dimensionally arranged in back-to-back pairs.

As shown in FIG. 2b, at least a third interior angle C is formed between the second light-facing face 22 and the first light-facing face 21, so that a plurality of interior angles is formed between the second light-facing face 22 and the first light-facing face 21, and even a free-form surface is formed. In some embodiments, the third interior angle C may be greater than or equal to 120° and less than or equal to 160°.

The microstructure 20 may be, but is not limited to, one of ethylene-tetrafluoroethylene (ETFE), polymethyl methacrylate (PMMA), polycarbonate (PC), or liquid optically clear resin.

The second refractive index n₂ is greater than or equal to 1.30 and less than or equal to 1.49.

In some embodiments, the microstructured light-collection film structure 100 of the present invention may further include an anti-reflective film 30. The anti-reflective film 30 may cover the microstructures 20. In some embodiments, the anti-reflective film 30 may have a first refractive index n₁. The first refractive index n₁ of the anti-reflective film 30 is less than the second refractive index n₂ of each microstructure 20. The second refractive index n₂ of each microstructure 20 is less than the third refractive index n₃ of the normal light-receiving optical film 10. However, space beyond the anti-reflective film 30 (that is, above the anti-reflective film 30 as shown in FIG. 2a and FIG. 2b) has a reflexive index no of air.

The anti-reflective film 30 may be but is not limited to anti-reflection liquid optical clear resin (AR Optical Clear Resin).

The first refractive index n₁ is greater than or equal to 1.01 and less than or equal to 1.30.

Preferably, n₁=n₀ may be selected during material selection in the process of microstructure optimization design. At this point, n₂ can be made from self-cleaning, dust-resistant materials, such as but not limited to ethylene-tetrafluoroethylene (ETFE).

The normal light-receiving optical film 10 may be, but is not limited to, the liquid optical clear resin or an optical clear adhesive.

The third refractive index n₃ is greater than or equal to 1.40 and less than or equal to 1.68.

Preferably, n₃=n₂ may be selected during material selection in the process of microstructure optimization design.

In some embodiments, the microstructured light-collection film structure 100 of the present invention may further include an optical adhesive 40. The optical adhesive 40 may be arranged below the normal light-receiving optical film 10. The optical adhesive 40 may have a fourth refractive index n₄, and the third refractive index n₃ of the normal light-receiving optical film 10 is less than the fourth refractive index n₄ of the optical adhesive 40.

The optical adhesive 40 may be, but not limited to, one of ethylene vinyl acetate (EVA), polyolefin elastomer (POE), or co-extrusion POE (EPE).

The fourth refractive index n₄ is greater than or equal to 1.45 and less than or equal to 1.70.

As shown in FIG. 2a to FIG. 2b and FIG. 4a to FIG. 4b, in the microstructured light-collection film structure 100 according to the first embodiment of the present invention, by means of the microstructures 20 in a symmetrical array arrangement and having the latitude position optimization function, a receiving angle of the microstructured light-collection film is expanded such that in addition to solar rays normally incident at an angle of 0°, solar rays L1 and L2 (incident at angles of 10°-80° and 80°-10° respectively) may be received around the clock (including in spring, summer, autumn, and winter, from sunrise to sunset, ambient light, and the like), to improve efficiency of exposure to sunlight, so as to achieve a real building integrated solar module/system (BIPV/BIPVs) capable of collecting sunlight or ambient light with high efficiency and gain, thereby greatly improving power generation efficiency of the system and reducing the levelized cost of electricity (LCOE) per kilowatt-hour.

Referring to FIG. 2a to FIG. 2b and FIG. 4a to FIG. 4b, the microstructured light-collection film structure 100 according to the first embodiment of the present invention may be installed on various inorganic/organic photovoltaic chips/photoelectric sensors/and a module 200 thereof, so that the microstructured light-collection film structure 100 of the present invention and various inorganic/organic photovoltaic chips/photoelectric sensors/and the module 200 thereof are integrally formed as a microstructured light-collection solar module 300.

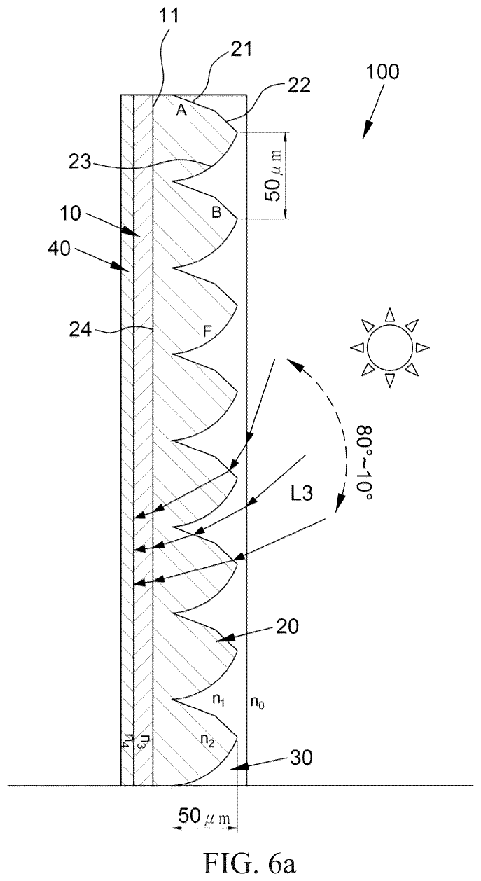

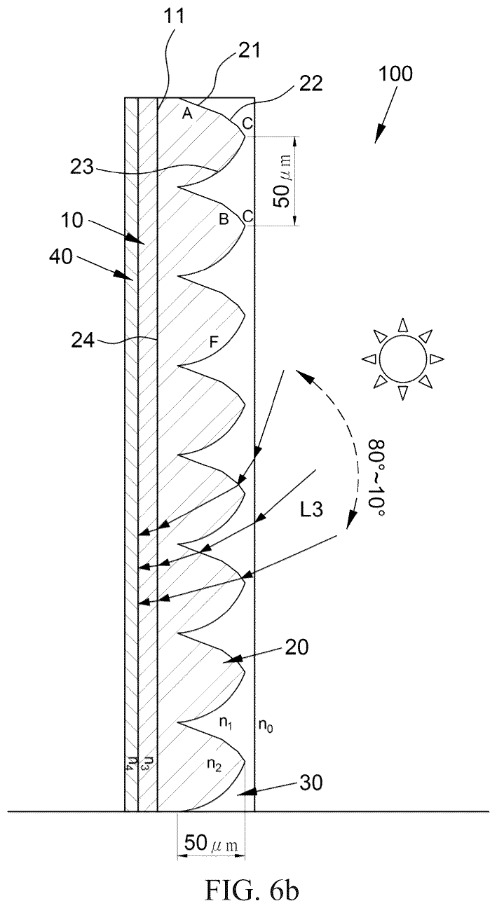

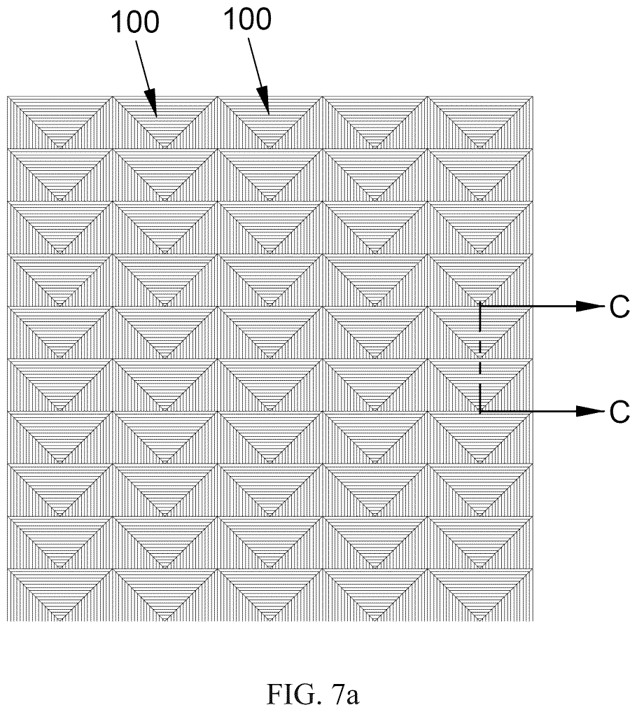

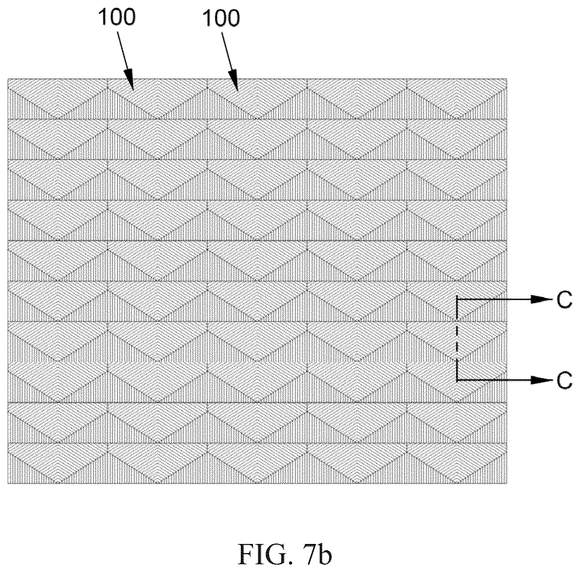

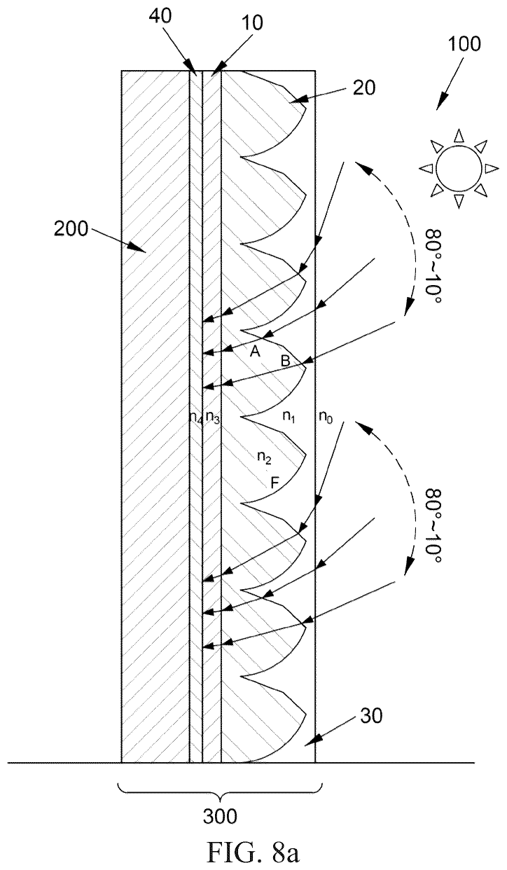

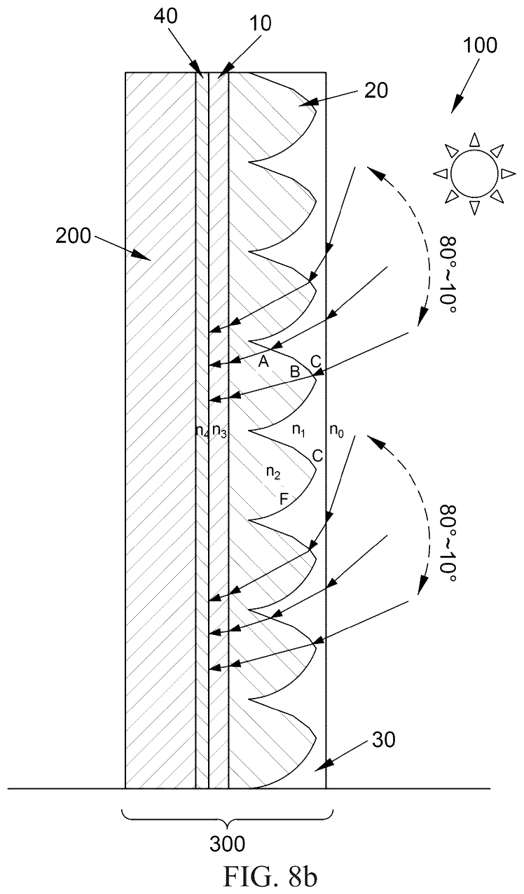

FIG. 5 is a 3D top view of a microstructured light-collection film structure according to the present invention. FIG. 6a to FIG. 6b are schematic cross-sectional views of a microstructured light-collection film structure according to the present invention installed in a direction perpendicular (orthogonal) to the ground and taken along a section line C-C of FIG. 5. FIG. 7a to FIG. 7b are schematic top views showing a microstructured light-collection film structure according to a second embodiment of the present invention in a linear array arrangement and receiving light multi-dimensionally. FIG. 8a to FIG. 8b are schematic cross-sectional views of a microstructured light-collection film structure according to the present invention applied to a solar module and taken along the section line C-C of FIG. 7a. The microstructured light-collection film structure according to the second embodiment of the present invention is the same as or similar to the foregoing microstructured light-collection film structure 100 of the first embodiment. Therefore, the same elements are denoted by the same element number.

Referring to FIG. 5 and FIG. 6a to FIG. 6b, the microstructured light-collection film structure 100 according to the second embodiment of the present invention includes a normal light-receiving optical film 10 and a plurality of microstructures 20.

When the microstructured light-collection film structure 100 is installed in the direction perpendicular (orthogonal) to the ground, the microstructured light-collection film structure may have an installation angle in a range of 90°+10°, or is optimized at a specific angle (such as the Leaning Tower of Pisa) and still has the light-collection function in all weather (including spring, summer, autumn, and winter, sunrise to sunset, and ambient light).

The normal light-receiving optical film 10 may have a light-receiving face 11. In some embodiments, the normal light-receiving optical film has a third refractive index n₃.

Referring to FIG. 5 and FIG. 7a to FIG. 7b, the plurality of microstructures 20 may be in an array arrangement and arranged on the light-receiving face 11 of the normal light-receiving optical film 10. A difference between the array arrangement in the second embodiment and the array arrangement in the first embodiment lies in the array arrangement in the second embodiment may be a linear array arrangement, including at least a circular linear array arrangement, a polygonal linear array arrangement, and a single-axis linear array arrangement. In FIG. 1, the array arrangement is a quadrilateral (offset) linear array arrangement, and in FIG. 3, the array arrangement is a quadrilateral (centered) linear array arrangement.

Referring to FIG. 6a to FIG. 6b again, each microstructure 20 may have a second refractive index n₂, and may include a bottom face 24, a first light-facing face 21, a second light-facing face 22, and a third light-facing face 23. The first light-facing face 21 may extend upward from an end of the bottom face 24, and a first interior angle A is formed between the first light-facing face 21 and the bottom face 24. In some embodiments, the first interior angle A may be greater than or equal to 50° and less than or equal to 80°. In FIG. 6, the first interior angle A is illustrated as 70°. The second light-facing face 22 may be connected to an end of the first light-facing face 21 away from an end thereof connected to the bottom face 24 and extend upward, and a second interior angle B is formed between the second light-facing face 22 and the first light-facing face 21. In some embodiments, the second interior angle B may be greater than or equal to 120° and less than or equal to 175°. In FIG. 6a, the second interior angle B is illustrated as 150°. One end of the third light-facing face 23 may be connected to an end of the second light-facing face 22 away from an end thereof connected to the first light-facing face 21 and extend downward, and an other end of the third light-facing face 23 is connected to an end of the bottom face 24 away from the end thereof connected to the first light-facing face 21. In some embodiments, the third light-facing face 23 has a convex arc F in the form of a free-form surface. In some embodiments, a height of each microstructure 20 may be 50 μm, and a distance between two adjacent microstructures 20 may be 50 μm, but the present invention is not limited thereto.

As shown in FIG. 6b, at least a third interior angle C is formed between the second light-facing face 22 and the first light-facing face 21, so that a plurality of interior angles is formed between the second light-facing face 22 and the first light-facing face 21, and even a free-form surface is formed. In some embodiments, the third interior angle C may be greater than or equal to 120° and less than or equal to 160°.

In some embodiments, the microstructured light-collection film structure 100 of the present invention may further include an anti-reflective film 30. The anti-reflective film 30 may cover the microstructures 20. In some embodiments, the anti-reflective film 30 may have a first refractive index n₁. The first refractive index n₁ of the anti-reflective film 30 is less than the second refractive index n₂ of each microstructure 20. The second refractive index n₂ of each microstructure 20 is less than the third refractive index n₃ of the normal light-receiving optical film 10. However, space beyond the anti-reflective film 30 (that is, above the anti-reflective film 30 as shown in FIG. 6a) has a reflexive index n₀ of air.

In some embodiments, the microstructured light-collection film structure 100 of the present invention may further include an optical adhesive 40. The optical adhesive 40 may be arranged below the normal light-receiving optical film 10. The optical adhesive 40 may have a fourth refractive index n₄, and the third refractive index n₃ of the normal light-receiving optical film 10 is less than the fourth refractive index n₄ of the optical adhesive 40.

As shown in FIG. 6a to FIG. 6b and FIG. 8a to FIG. 8b, in the microstructured light-collection film structure 100 of the second embodiment of the present invention, by means of the microstructures 20 in a symmetrical array arrangement and having the latitude position optimization function, a receiving angle of the microstructured light-collection film is expanded such that in addition to solar rays normally incident at an angle of 0°, all solar rays L3 (incident at angles of 80°-10° as shown in FIG. 6a to FIG. 6b or 80°-10° as shown in FIG. 8a to FIG. 8b and respectively) may be received, to improve efficiency of exposure to sunlight, so as to achieve a real building integrated solar module/system (BIPV/BIPVs) capable of collecting sunlight or ambient light with high efficiency and gain, thereby greatly improving power generation efficiency of the system and reducing the levelized cost of electricity (LCOE) per kilowatt-hour.

As shown in FIG. 8b, at least a third interior angle C is formed between the second light-facing face 22 and the first light-facing face 21, so that a plurality of interior angles is formed between the second light-facing face 22 and the first light-facing face 21, and even a free-form surface is formed. In some embodiments, the third interior angle C may be greater than or equal to 120° and less than or equal to 160°.

Referring to FIG. 6a to FIG. 6b and FIG. 8a to FIG. 8b, the microstructured light-collection film structure 100 according to the second embodiment of the present invention may be installed on various inorganic/organic photovoltaic chips/photoelectric sensors/and a module 200 thereof, so that the microstructured light-collection film structure 100 of the present invention and various inorganic/organic photovoltaic chips/photoelectric sensors/and the module 200 thereof are integrally formed as a microstructured light-collection solar module 300.

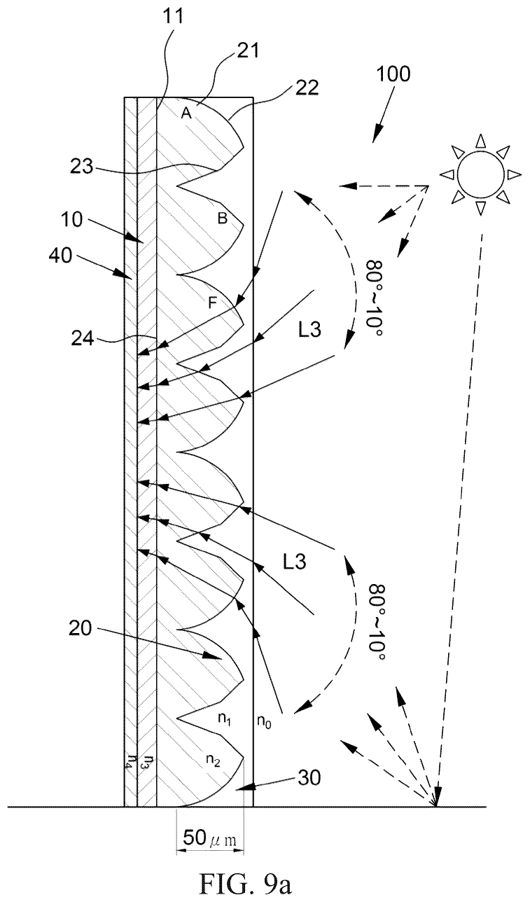

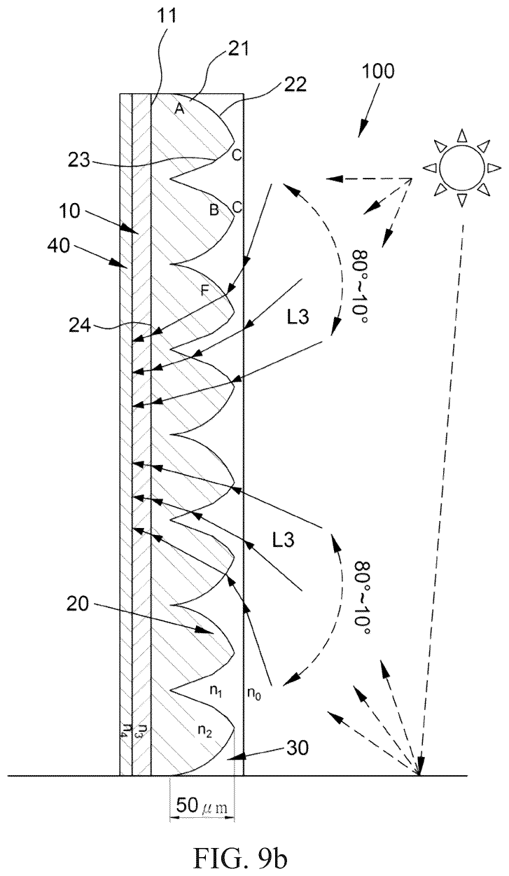

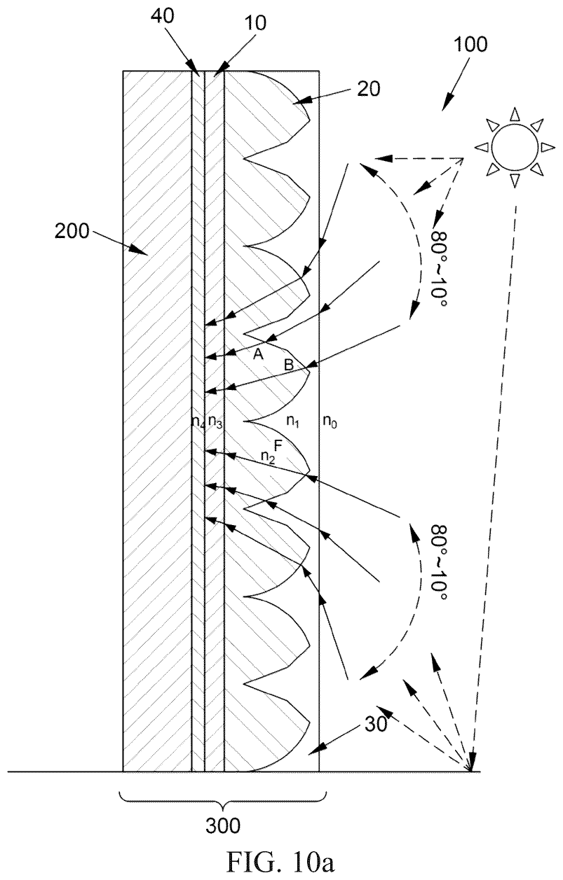

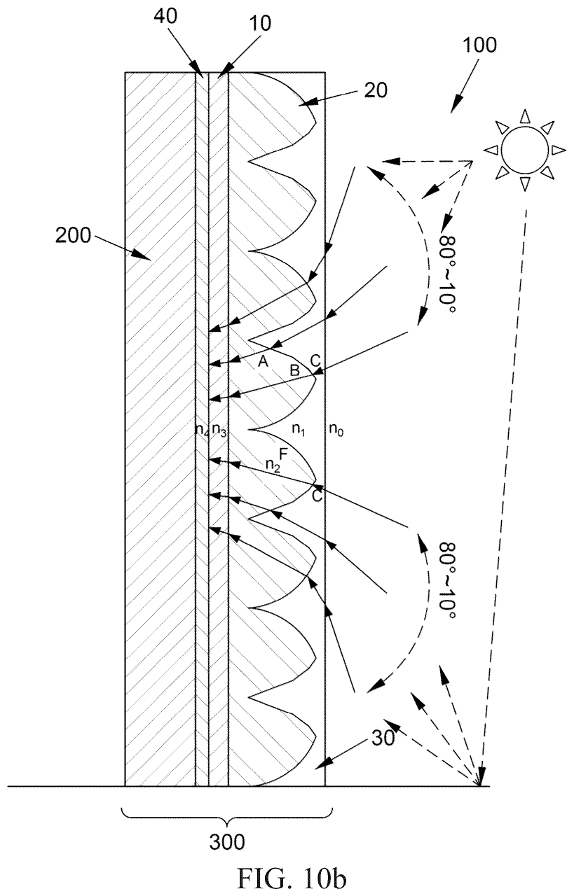

FIG. 9a to FIG. 9b are embodiments in which a microstructured light-collection film structure according to the present invention is installed (operated) in a direction perpendicular (orthogonal) to the ground. FIG. 10a to FIG. 10b are embodiments in which a microstructured light-collection film structure according to the present invention is applied to a solar module and installed (operated) in a direction perpendicular (orthogonal) to the ground.

As shown in FIG. 9a to FIG. 9b and FIG. 10a to FIG. 10b, the microstructured light-collection film structure of the present invention may reflect sunlight/ambient light through other buildings or the ground when applied to a solar module.

When the microstructured light-collection film structure 100 is applied to the solar module and installed in the direction perpendicular (orthogonal) to the ground, the microstructured light-collection film structure may have an installation angle in a range of 90°±10°, or is optimized at a specific angle (such as the Leaning Tower of Pisa) and still has the light-collection function in all weather (including spring, summer, autumn, and winter, sunrise to sunset, and ambient light).

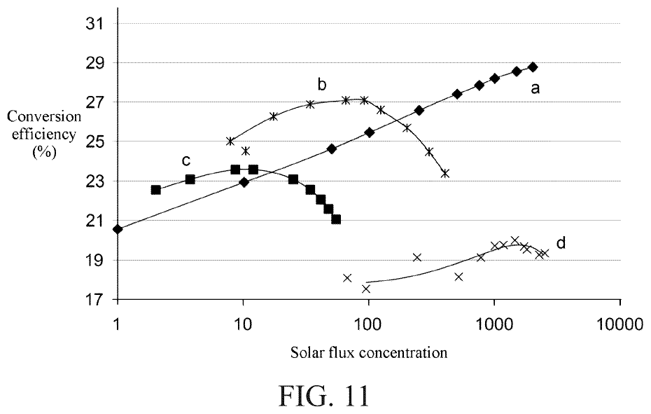

FIG. 11 is a schematic diagram of a curve showing a functional relationship between photoelectric conversion efficiency and a solar flux concentration of a microstructured light-collection film structure according to the present invention. Referring to FIG. 11, a functional relationship between conversion efficiency of the microstructured light-collection film structure 100 of the present invention and a solar flux concentration is shown, where a curve a represents a vertical structure with a width of 43.6 μm and a height of 60 μm, with back recombination=1000 cm/s and front recombination=10 cm/s (a), a curve b represents the technique disclosed by Slade et al. in the related art, a curve c represents a silver cell, and a curve d represents the technique disclosed by Sater et al. in the related art. It is obviously seen that the microstructured light-collection film structure 100 (curve A) of the present invention thoroughly deconstructs the inefficiency of the traditional complex sun tracking structure and the fixed bracket structure and other various related light-collection module technologies having been disclosed, so as to greatly improve photoelectric conversion efficiency of the traditional solar module and surpass the current power generation efficiency problem of the traditional solar module in the fixed bracket structure, thereby greatly improving the power generation efficiency of the system and reducing the levelized cost of electricity per kilowatt-hour.

Based on the above, in the microstructured light-collection film structure 100 of the present invention and the microstructured light-collection solar module 300 combined with various inorganic/organic photovoltaic chips/photoelectric sensors/and the module 200 thereof, based on the facing directions of different light-facing faces (that is, the first light-facing face 21, the second light-facing face 22, and the third light-facing face 23, it could even be optimized to create more light-receiving surfaces, approaching the formation of a second freeform surface.) of the microstructure 20 on the optical film (that is, the normal light-receiving optical film 10), a microstructured profile defined in a specific latitude range is optimized to collect solar energy/ambient light in the direction perpendicular to sunlight or the direction perpendicular to ground, so as to achieve a real building integrated solar module/system (BIPV/BIPVs) capable of collecting sunlight or ambient light with high efficiency and gain, thereby greatly improving power generation efficiency of the system and reducing the levelized cost of electricity (LCOE) per kilowatt-hour.

What is claimed is:

1. A microstructured light-collection film structure, comprising:
a normal light-receiving optical film, having a light-receiving face; and
a plurality of microstructures, in an array arrangement and arranged on the light-receiving face of the normal light-receiving optical film, wherein each of the microstructures comprises a bottom face, a first light-facing face, a second light-facing face, and a third light-facing face, the first light-facing face extends upward from an end of the bottom face, a first interior angle is formed between the first light-facing face and the bottom face, the second light-facing face is connected to an end of the first light-facing face away from the bottom face and extends upward, a second interior angle is formed between the second light-facing face and the first light-facing face, one end of the third light-facing face is connected to an end of the second light-facing face away from the end thereof connected to the first light-facing face and extends downward, and an other end of the third light-facing face is connected to an end of the bottom face away from the end thereof connected to the first light-facing face.

2. The microstructured light-collection film structure according to claim 1, wherein the third light-facing face has a convex arc in the form of a free-form surface.

3. The microstructured light-collection film structure according to claim 2, further comprising an anti-reflective film covering the microstructures, wherein the anti-reflective film has a first refractive index n₁.

4. The microstructured light-collection film structure according to claim 3, wherein each of the microstructures has a second refractive index n₂, and the first refractive index n₁ is less than the second refractive index n₂.

5. The microstructured light-collection film structure according to claim 4, wherein the normal light-receiving optical film has a third refractive index n₃, and the second refractive index n₂ is less than the third refractive index n₃.

6. The microstructured light-collection film structure according to claim 5, further comprising an optical adhesive arranged below the normal light-receiving optical film, wherein the optical adhesive has a fourth refractive index n₄, and the third refractive index n₃ is less than the fourth refractive index n₄.

7. The microstructured light-collection film structure according to claim 1, wherein the first interior angle is greater than or equal to 50° and less than or equal to 80°.

8. The microstructured light-collection film structure according to claim 7, wherein the second interior angle is greater than or equal to 120° and less than or equal to 175°, at least a third interior angle is formed between the second light-facing face and the first light-facing face, and the third interior angle is greater than or equal to 130° and less than or equal to 160°.

9. The microstructured light-collection film structure according to claim 1, wherein the array arrangement is a symmetrical array arrangement, comprising at least but not limited to a circular symmetrical array arrangement, a polygonal symmetrical array arrangement, and a single-axis symmetrical array arrangement.

10. The microstructured light-collection film structure according to claim 1, wherein the array arrangement is a linear array arrangement, comprising at least but not limited to a circular linear array arrangement, a polygonal linear array arrangement, and a single-axis linear array arrangement.
